(19) United States
(12) Patent Application Publication
(10) Pub. No.: US 2026/0214964 A1
(43) Pub. Date: Jul. 23, 2026

(54) SEMICONDUCTOR STRUCTURE WITH STACKED TRANSISTORS

(71) Applicant: TAIWAN SEMICONDUCTOR MANUFACTURING COMPANY, LTD., Hsinchu (TW)

(72) Inventors: Kai-Chieh YANG, New Taipei City (TW); Hsu-Kai CHANG, Hsinchu (TW); Wei-Yen WOON, Taoyuan City (TW); Szuya LIAO, Hsinchu County (TW)

(73) Assignee: TAIWAN SEMICONDUCTOR MANUFACTURING COMPANY, LTD., Hsinchu (TW)

(21) Appl. No.: 19/030,434

(22) Filed: Jan. 17, 2025

(51) Int. Cl. H10D 84/01; H10D 84/85

(52) U.S. Cl. CPC H10D 84/0177; H10D 84/0167; H10D 84/0188; H10D 84/851; H10D 84/856

(57) ABSTRACT

A method includes following steps. A first semiconductor channel region and a second semiconductor channel region above the first semiconductor channel region are formed. A first work function layer surrounding the first semiconductor channel region and the second semiconductor channel region is formed. A first fill metal is deposited over the first work function layer. The first fill metal is etched back. The etched-back first fill metal has a non-linear top surface in a cross-sectional view. The non-linear top surface comprises a bottom segment and slanted segments extending upwards from opposite ends of the bottom segment. A second fill metal is deposited over the etched-back first fill metal.

### BACKGROUND

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (CFET) where an n-type multi-gate transistor and a p-type multi-gate transistor are stacked vertically, one over the other. While existing CFET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a complementary field-effect transistor (CFET) schematic in a three-dimensional view, in accordance with some embodiments.

FIGS. 2-14D are three-dimensional views and cross-sectional views of a CFET device 300 at various stages of manufacturing, in accordance with some embodiments of the present disclosure.

FIGS. 15-17C are cross-sectional views of a CFET device at various stages of manufacturing, in accordance with some other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced with the down-scaling of the integrated circuits.

According to various embodiments, CFETs are formed. A CFET includes a lower nanostructure-FET and an upper nanostructure-FET of a different conductivity type than the lower nanostructure-FET. Throughout the description, the terms “FET” and “transistor” are used interchangeably. In some embodiments, both the lower and upper nanostructure-FETs share a common high-k metal gate (HKMG) structure that vertically spans from the upper nanostructure-FET to the lower nanostructure-FET. This HKMG structure includes a fill metal serving to fill a gate trench that exposes both the lower and upper semiconductor nanostructures. As the number of semiconductor nanostructures increases (e.g., a total of four nanostructures, comprising two lower semiconductor nanostructures and two upper semiconductor nanostructures), the aspect ratio of the gate trench also increases. This heightened aspect ratio presents challenges for adequately filling the gate trench. Specifically, a higher aspect ratio can lead to the formation of unfilled voids within the fill metal structure deposited in the gate trench, potentially affecting the performance and reliability of the CFET.

To address this challenge, the present disclosure, in various embodiments, provides a deposition-etch-deposition (Dep-Etch-Dep) process for forming an improved gate fill metal structure with no or negligible void. This process begins with an initial deposition step to deposit a first fill metal, followed by an etching step to etch back the first fill metal, and followed by a final deposition step to deposit a second fill metal. The etching step between the initial deposition step and the final deposition step is performed to create a V-shaped profile on the top surface of the etched-back fill metal. This V-shaped profile facilitates the deposition of the second fill metal, minimizing void formation or reducing the size of any voids within the second fill metal, thereby enhancing the performance and reliability of the CFET.

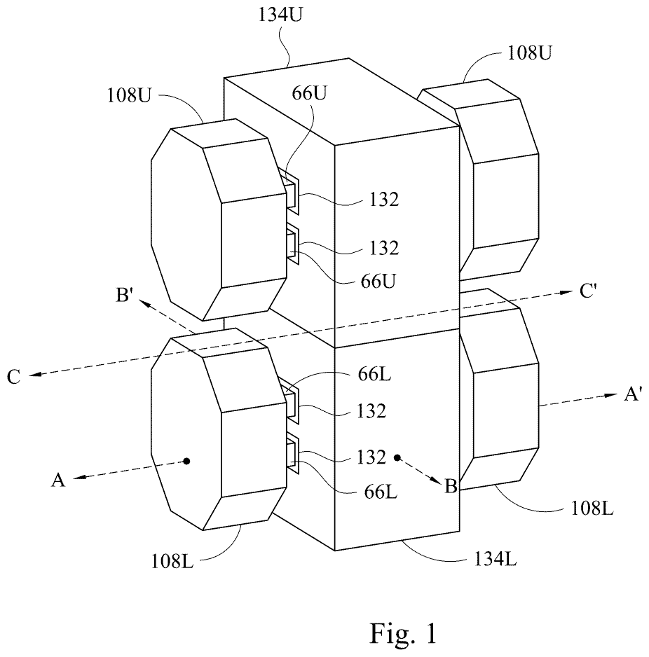

FIG. 1 illustrates an example of a CFET schematic, in accordance with some embodiments. FIG. 1 is a three-dimensional view, where some features of the CFETs are omitted for illustration clarity. While Gate-All-Around (GAA) transistors (such as nanostructure-FETs) are illustrated, the concept of the present disclosure can also be applied to the formation of other types of transistors such as planar transistors, Fin Field-Effect Transistors (FinFETs), or the like. Furthermore, in the illustrated examples, the upper FETs are PFETs, and lower FETs are NFETs, while in other embodiments, upper FETs may also be NFETs, and the lower FETs may be PFET.

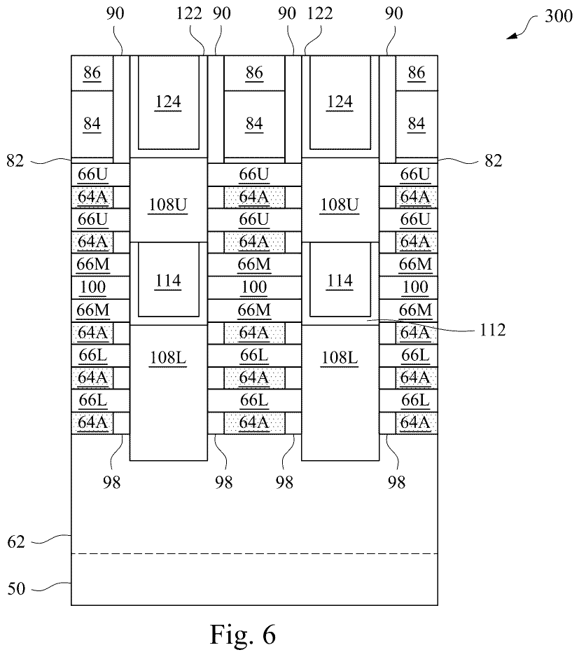

The CFETs include multiple vertically stacked nanostructure-FETs (e.g., nanowire FETs, nanosheet FETs, multi bridge channel (MBC) FETs, nanoribbon FETs, gate-all-around (GAA) FETs, or the like). For example, a CFET may include a lower nanostructure-FET of a first device type (e.g., n-type/p-type) and an upper nanostructure-FET of a second device type (e.g., p-type/n-type) that is opposite the first device type. Specifically, the CFET may include a lower PMOS transistor and an upper NMOS transistor, or the CFET may include a lower NMOS transistor and an upper PMOS transistor. Each of the nanostructure-FETs include semiconductor nanostructures 66 (including lower semiconductor nanostructures 66L and upper semiconductor nanostructures 66U), where the semiconductor nanostructures 66 act as channel regions (also referred to as channel layers, semiconductor channels regions, or semiconductor channel layers) for the nanostructure-FETs. The semiconductor nanostructures 66 may be nanosheets, nanowires, or the like. The lower semiconductor nanostructures 66L are for a lower nanostructure-FET and the upper semiconductor nanostructures 66U are for an upper nanostructure-FET. A nanostructure isolation material (not explicitly illustrated in FIG. 1, see 100 in FIG. 6) may be used to separate and electrically isolate the upper semiconductor nanostructures 66U from the lower semiconductor nanostructures 66L.

Gate dielectrics 132 are along top surfaces, sidewalls, and bottom surfaces of the semiconductor nanostructures 66. Gate electrodes 134 (including a lower gate electrode 134L and an upper gate electrode 134U) are over the gate dielectrics 132 and around the semiconductor nanostructures 66. Source/drain regions 108 (including lower epitaxial source/drain regions 108L and upper epitaxial source/drain regions 108U) are disposed at opposing sides of the gate dielectrics 132 and the gate electrodes 134. Source/drain region(s) 108 may refer to a source or a drain, individually or collectively dependent upon the context. Isolation features may be formed to separate desired ones of the source/drain regions 108 and/or desired ones of the gate electrodes 134. For example, a lower gate electrode 134L may optionally be separated from an upper gate electrode 134U by an isolation layer. Alternatively, a lower gate electrode 134L may be coupled to an upper gate electrode 134U. Further, the upper epitaxial source/drain regions 108U may be separated from lower epitaxial source/drain regions 108L by one or more dielectric layers. The isolation features between channel regions, gates, and source/drain regions allow for vertically stacked transistors, thereby improving device density. Because of the vertically stacked nature of CFETs, the schematic may also be referred to as stacking transistors or folding transistors.

FIG. 1 further illustrates reference cross-sections that are used in later figures. Cross-section A-A′ is parallel to a longitudinal axis of the semiconductor nanostructures 66 of a CFET and in a direction of, for example, a current flow between the source/drain regions 108 of the CFET. Cross-section B-B′ is perpendicular to cross-section A-A′ and along a longitudinal axis of a gate electrode 134 of a CFET. Cross-section C-C′ is parallel to cross-section A-A′ and extends through a portion of the gate electrode 134 laterally offset from the semiconductor nanostructures 66. Subsequent figures refer to these reference cross-sections for clarity.

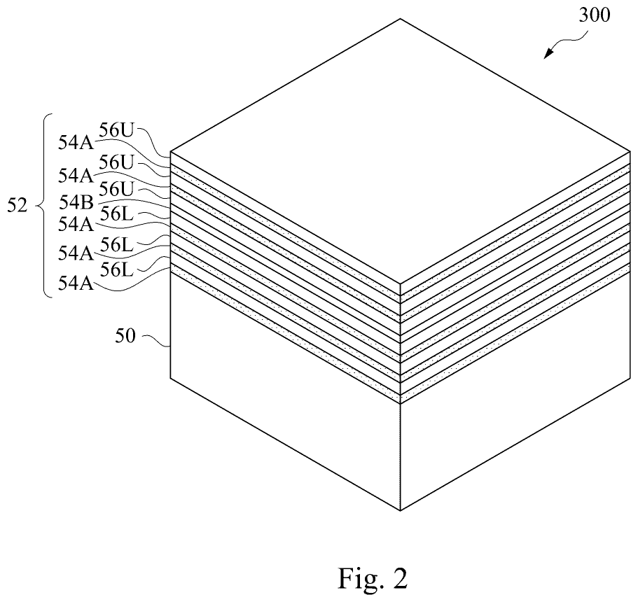

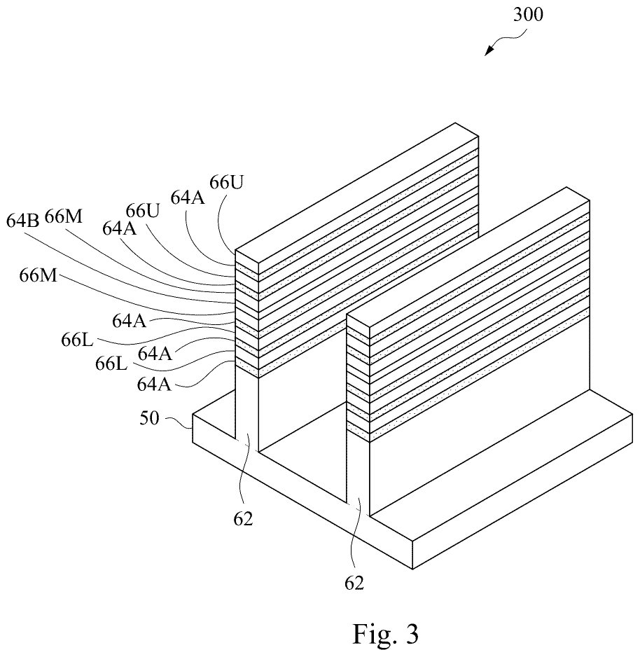

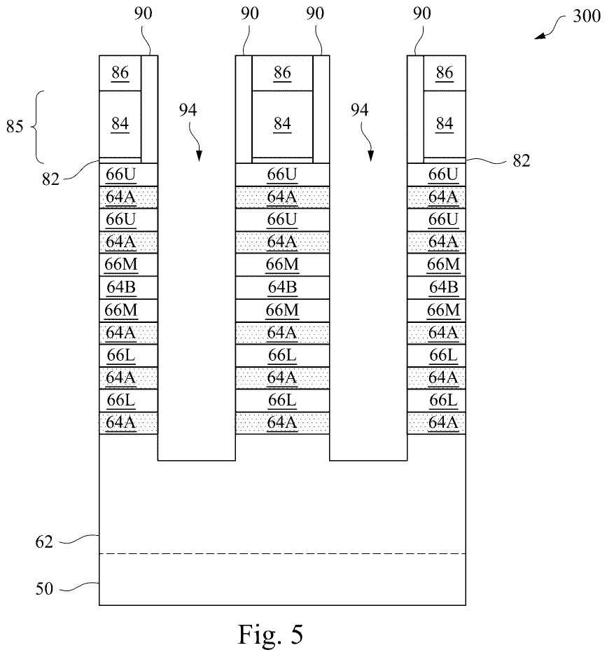

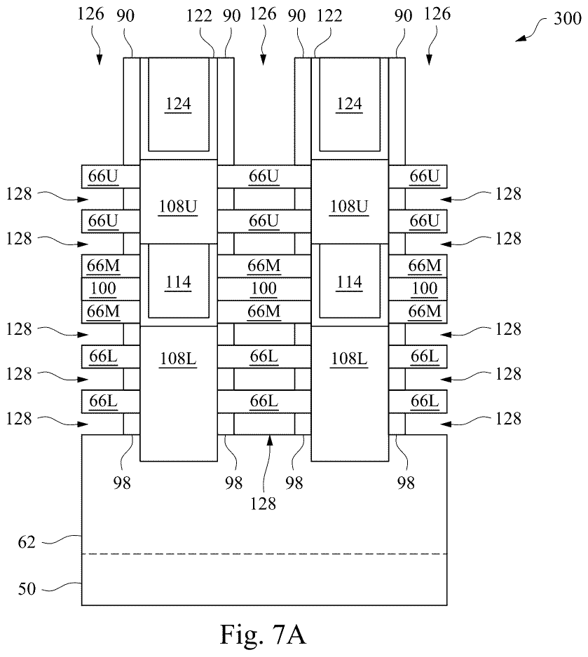

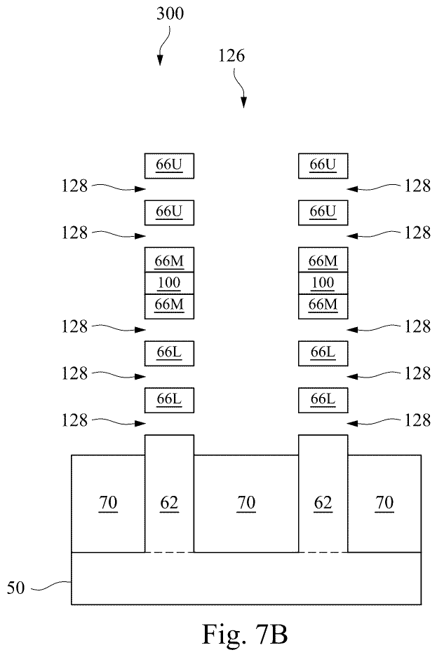

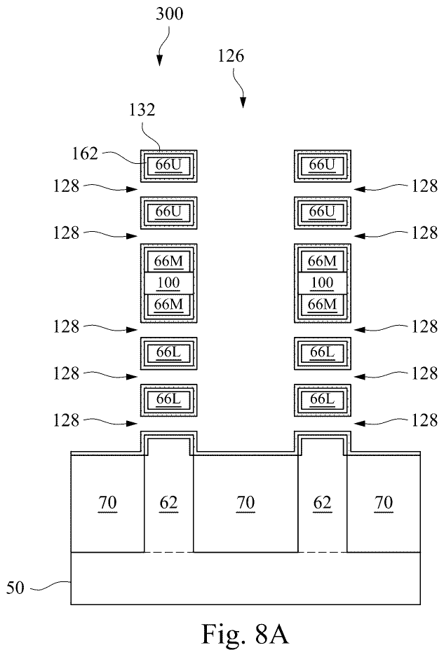

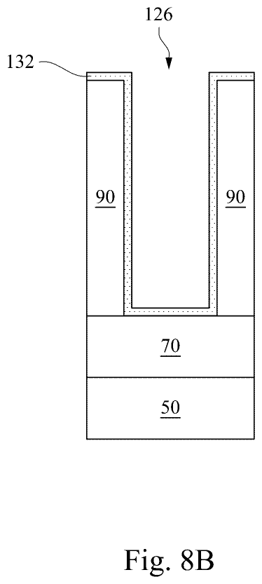

FIGS. 2-14C are three-dimensional views and cross-sectional views of a CFET device 300 at various stages of manufacturing, in accordance with some embodiments of the present disclosure. FIGS. 2, 3, and 4 are three-dimensional views showing a similar three-dimensional view as FIG. 1. FIGS. 5, 6, 7A, and 14C illustrate cross-sectional views along a similar cross-section as reference cross-section A-A′ in FIG. 1. FIGS. 7B, 8A, 9A, 14B, and 14D illustrate cross-sectional views along a similar cross-section as reference cross-section B-B′ in FIG. 1. FIGS. 8B, 9B, and 10-14A illustrate cross-sectional views along a similar cross-section as reference cross-section C-C′ in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including carbon-doped silicon, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

A multi-layer stack 52 is formed over the substrate 50. The multi-layer stack 52 includes alternating dummy layers 54 (including first dummy layers 54A and a second dummy layer 54B) and semiconductor layers 56 (including lower semiconductor layers 56L and upper semiconductor layers 56U). The lower semiconductor layers 56L and a subset of the first dummy layers 54A are disposed below the second dummy layer 54B. The upper semiconductor layers 56U and another subset of the first dummy layers 54A are disposed above the second dummy layer 54B. As subsequently described in greater detail, the dummy layers 54 will be removed and the semiconductor layers 56 will be patterned to form channel regions of CFETs. Specifically, the lower semiconductor layers 56L will be patterned to form channel regions of the lower nanostructure-FETs of the CFETs, and the upper semiconductor layers 56U will be patterned to form channel regions of the upper nanostructure-FETs of the CFETs.

The multi-layer stack 52 is illustrated as including six of the dummy layers 54 and six of the semiconductor layers 56. It is appreciated that the multi-layer stack 52 may include any number of the dummy layers 54 and the semiconductor layers 56. Each layer of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like.

The first dummy layers 54A are formed of a first semiconductor material, and the second dummy layer 54B is formed of a second semiconductor material. The first and second semiconductor materials may be selected from the candidate semiconductor materials of the substrate 50. The semiconductor materials of the first dummy layers 54A and the second dummy layer 54B will be subsequently described in greater detail. The first and second semiconductor materials have a high etching selectivity to one another. As such, the material of the second dummy layer 54B may be removed at a faster rate than the material of the first dummy layers 54A in subsequent processing.

The semiconductor layers 56 (including the lower semiconductor layers 56L and upper semiconductor layers 56U) are formed of one or more semiconductor material(s). The semiconductor material(s) may be selected from the candidate semiconductor materials of the substrate 50. In some embodiments, the semiconductor layers 56 are formed of a group IV-V material or a group III-V material. The lower semiconductor layers 56L and the upper semiconductor layers 56U may be formed of the same semiconductor material, or may be formed of different semiconductor materials. In some embodiments, the lower semiconductor layers 56L and the upper semiconductor layers 56U are both be formed of a semiconductor material suitable for p-type devices and n-type devices, such as silicon. In some embodiments, the lower semiconductor layers 56L are formed of a semiconductor material suitable for p-type devices, such as germanium or silicon-germanium, and the upper semiconductor layers 56U are formed of a semiconductor material suitable for n-type devices, such as silicon or carbon-doped silicon. The semiconductor material(s) of the semiconductor layers 56 will be subsequently described in greater detail. The semiconductor material(s) of the semiconductor layers 56 have a high etching selectivity to the semiconductor materials of the dummy layers 54. As such, the materials of the dummy layers 54 may be removed at a faster rate than the material of the semiconductor layers 56 in subsequent processing.

Some layers of the multi-layer stack 52 may be thicker than other layers of the multi-layer stack 52. The thickness of the second dummy layer 54B may be different (e.g., greater or less) than the thickness of each of the first dummy layers 54A. In some embodiments, the second dummy layer 54B has a large thickness, such as a greater thickness than each of the first dummy layers 54A. Forming the second dummy layer 54B to a large thickness allows the second dummy layer 54B to be more easily removed in subsequently processing. Additionally, the thickness of each of the semiconductor layers 56 may be different (e.g., greater or less) than the thickness(es) of each of the first dummy layers 54A and/or the second dummy layer 54B. In some embodiments, each of the semiconductor layers 56 may be thicker than each of the dummy layers 54.

In some embodiments, the first dummy layers 54A are formed of silicon-germanium with a first germanium atomic percentage, the second dummy layer 54B is formed of silicon-germanium with a second germanium atomic percentage that is higher than the first germanium atomic percentage. The difference between the second germanium atomic percentage and the first germanium atomic percentage may be higher than about 25 percent, and may be in the range between about 35 percent and about 75 percent. The higher germanium atomic percentage allows the second dummy layer 54B to be etched at a faster rate than the first dummy layers 54A, and allow the second dummy layer 54B to be completed removed during a subsequent etching process, as discussed hereinafter.

In FIG. 3, fins 62 are formed in the substrate 50 and nanostructures 64, 66 (including first dummy nanostructures 64A, second dummy nanostructures 64B, lower semiconductor nanostructures 66L, middle semiconductor nanostructures 66M, and upper semiconductor nanostructures 66U) are formed in the multi-layer stack 52. In some embodiments, the nanostructures 64, 66 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64, 66 by etching the multi-layer stack 52 may define the first dummy nanostructures 64A from the first dummy layers 54A, the second dummy nanostructures 64B from the second dummy layer 54B, the lower semiconductor nanostructures 66L from some of the lower semiconductor layers 56L, the upper semiconductor nanostructures 66U from some of the upper semiconductor layers 56U, and the middle semiconductor nanostructures 66M from some of the lower semiconductor layers 56L and some of the upper semiconductor layers 56U. The first dummy nanostructures 64A and the second dummy nanostructures 64B may further be collectively referred to as the dummy nanostructures 64. The lower semiconductor nanostructures 66L and the upper semiconductor nanostructures 66U may further be collectively referred to as the semiconductor nanostructures 66.

As subsequently described in greater detail, the dummy nanostructures 64 will be removed to form vertically arranged channel regions of CFETs. Specifically, the lower semiconductor nanostructures 66L will act as channel regions for lower nanostructure-FETs of the CFETs. Additionally, the upper semiconductor nanostructures 66U will act as channel regions for upper nanostructure-FETs of the CFETs.

The middle semiconductor nanostructures 66M are the semiconductor nanostructures 66 that are directly above/below (e.g., in contact with) the second dummy nanostructures 64B. Depending on the heights of subsequently formed source/drain regions, the middle semiconductor nanostructures 66M may or may not adjoin any source/drain regions and may or may not act as functional channel regions for the CFETs. The second dummy nanostructures 64B will be subsequently replaced with isolation structures. The isolation structures and the middle semiconductor nanostructures 66M may define boundaries of the lower nanostructure-FETs and the upper nanostructure-FETs.

The fins 62 and the nanostructures 64, 66 may be patterned by any suitable method. For example, the fins 62 and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64, 66. In some embodiments, a mask (or other layer) may remain on the nanostructures 64, 66.

Although each of the fins 62 and the nanostructures 64, 66 are illustrated as having a constant width throughout, in other embodiments, the fins 62 and/or the nanostructures 64, 66 may have tapered sidewalls such that a width of each of the fins 62 and/or the nanostructures 64, 66 continuously increases in a direction towards the substrate 50. In such embodiments, each of the nanostructures 64, 66 may have a different width and be trapezoidal in cross-section view.

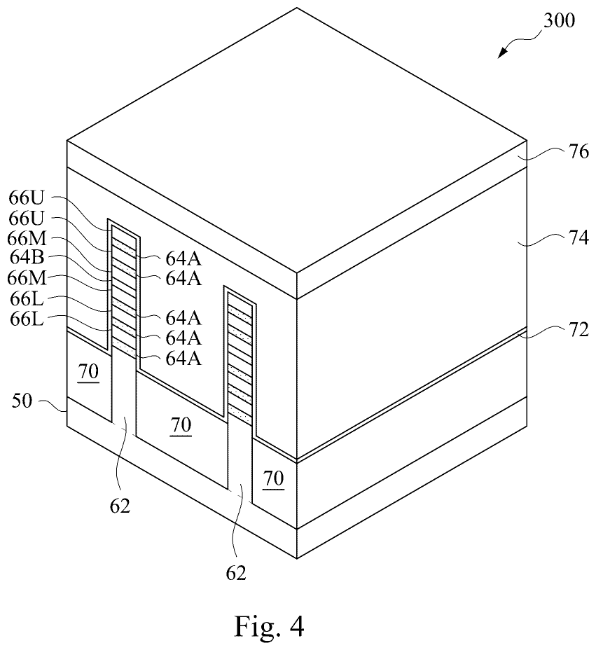

In FIG. 4, isolation regions 70 are formed adjacent to the fins 62. The isolation regions 70 may be formed by depositing an insulating material over the substrate 50, the fins 62, and nanostructures 64, 66, and between adjacent fins 62. The insulating material may be an oxide, such as silicon oxide, a nitride, the like, or a combination thereof, and may be formed by high-density plasma chemical vapor deposition (HDP-CVD), flowable chemical vapor deposition (FCVD), the like, or a combination thereof. Other insulating materials formed by any acceptable process may be used. In some embodiments, the insulating material is silicon oxide formed by an FCVD process. An anneal process may be performed once the insulating material is formed. In an embodiment, the insulating material is formed such that excess insulating material covers the nanostructures 64, 66. Although the insulating material is illustrated as a single layer, some embodiments may utilize multiple layers. For example, in some embodiments a liner (not separately illustrated) may first be formed along a surface of the substrate 50, the fins 62, and the nanostructures 64, 66. Thereafter, a fill material, such as one of the previously described insulating materials may be formed over the liner.

A removal process is then applied to the insulating material to remove excess insulating material over the nanostructures 64, 66. In some embodiments, a planarization process such as a chemical mechanical polish (CMP), an etch-back process, combinations thereof, or the like may be utilized. The planarization process exposes the nanostructures 64, 66 such that top surfaces of the nanostructures 64, 66 and the insulating material are level after the planarization process is complete.

The insulating material is then recessed to form the isolation regions 70. The insulating material is recessed such that upper portions of the fins 62 protrude from between neighboring isolation regions 70. Further, the top surfaces of the isolation regions 70 may have a flat surface as illustrated, a convex surface, a concave surface (such as dishing), or a combination thereof. The top surfaces of the isolation regions 70 may be formed flat, convex, and/or concave by an appropriate etch. The isolation regions 70 may be recessed using an etching process, such as one that is selective to the insulating material (e.g., selectively etches the insulating material at a faster rate than the materials of the fins 62 and the nanostructures 64, 66). For example, an oxide removal using, for example, dilute hydrofluoric (dHF) acid may be used.

In FIG. 4, a dummy dielectric layer 72 is formed on the fins 62 and/or the nanostructures 64, 66. The dummy dielectric layer 72 may be, for example, silicon oxide, silicon nitride, a combination thereof, or the like, and may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The mask layer 76 may be deposited over the dummy gate layer 74. The dummy gate layer 74 may be a conductive or non-conductive material and may be selected from a group including amorphous silicon, polycrystalline-silicon (polysilicon), poly-crystalline silicon-germanium (poly-SiGe), or the like. The dummy gate layer 74 may be deposited by physical vapor deposition (PVD), CVD, sputter deposition, or other techniques for depositing the selected material. The dummy gate layer 74 may be formed of other materials that have a high etching selectivity to insulating materials. The mask layer 76 may include, for example, silicon nitride, silicon oxynitride, or the like. In the illustrated embodiment, the dummy dielectric layer 72 covers the isolation regions 70, such that the dummy dielectric layer 72 extends between the dummy gate layer 74 and the isolation regions 70. In another embodiment, the dummy dielectric layer 72 covers only the fins 62 and/or the nanostructures 64, 66.

Next, in FIG. 5, the mask layer 76 is patterned using acceptable photolithography and etching techniques to form masks 86. The pattern of the masks 86 is then transferred to the dummy gate layer 74 and to the dummy dielectric layer 72 to form dummy gates 84 and dummy dielectrics 82, respectively. The dummy gates 84 and the dummy dielectrics 82 are collectively referred to as dummy gate stacks 85. The dummy gates 84 cover respective channel regions of the nanostructures 64, 66. The pattern of the masks 86 may be used to physically separate each of the dummy gates 84 from adjacent dummy gates 84. The dummy gates 84 may also have a lengthwise direction substantially perpendicular to the lengthwise direction of respective fins 62. The masks 86 can optionally be removed after patterning, such as by any acceptable etching technique.

In FIG. 5, gate spacers 90 are formed over the nanostructures 64, 66 and on exposed sidewalls of the masks 86 (if present), the dummy gates 84, and the dummy dielectrics 82. The gate spacers 90 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other dielectric materials formed by any acceptable process may be used. Any acceptable etch process, such as a dry etch, may be performed to pattern the dielectric material(s). The etching may be anisotropic. The dielectric material(s), when etched, have portions left on the sidewalls of the dummy gates 84 (thus forming the gate spacers 90). Fin spacers may also be formed as part of forming the gate spacers 90.

Source/drain recesses 94 are formed in the nanostructures 64, 66, and the fins 62. Epitaxial source/drain regions will be subsequently formed in the source/drain recesses 94. The source/drain recesses 94 may extend through the nanostructures 64, 66 and into the fins 62. The fins 62 may be etched such that bottom surfaces of the source/drain recesses 94 are disposed above, below, or level with the top surfaces of the isolation regions 70. The source/drain recesses 94 may be formed by etching the nanostructures 64, 66, and the substrate 50 using anisotropic etching processes, such as RIE, NBE, or the like. The gate spacers 90 and the dummy gates 84 mask portions of the nanostructures 64, 66, and the fins 62 during the etching processes used to form the source/drain recesses 94. A single etch process or multiple etch processes may be used to etch each layer of the nanostructures 64, 66, and the fins 62. Timed etch processes may be used to stop the etching of the source/drain recesses 94 after the source/drain recesses 94 reach a desired depth.

Next, in FIG. 6, inner spacers 98 and dielectric isolation layers 100 are formed. Forming inner spacers 98 and dielectric isolation layers 100 (also referred to as dielectric isolation nanostructures 100) may include an etching process that laterally etches the dummy nanostructures 64A and removes the dummy nanostructure 64B. The etching process may be isotropic and may be selective to the material of the dummy nanostructures 64, so that the dummy nanostructures 64 are etched at a faster rate than the semiconductor nanostructures 66. The etching process may also be selective to the material of the dummy nanostructures 64B, so that the dummy nanostructures 64B are etched at a faster rate than the dummy nanostructures 64A. In this manner, the dummy nanostructures 64B may be completely removed from between the middle semiconductor nanostructures 66M without completely removing the dummy nanostructures 64A. In some embodiments where the dummy nanostructures 64B are formed of germanium or silicon germanium with a higher germanium atomic percentage than the dummy nanostructures 64A, the dummy nanostructures 64A are formed of silicon germanium with a lower germanium atomic percentage than the dummy structures 64B, and the semiconductor nanostructures 66 are formed of silicon free from germanium, the etch process may comprise a dry etch process using chlorine-containing gas, with or without a plasma. Because the dummy gate stacks 85 wrap around sidewalls of the semiconductor nanostructures 66 (see FIG. 4), the dummy gate stacks 85 may support the upper semiconductor nanostructures 66U so that the upper semiconductor nanostructures 66U do not collapse upon removal of the dummy nanostructures 64B. Further, although sidewalls of the dummy nanostructures 64A are illustrated as being straight after the etching, the sidewalls may be concave or convex.

Inner spacers 98 are formed on sidewalls of the recessed dummy nanostructures 64A, and dielectric isolation layers 100 are formed between the middle semiconductor nanostructures 66M. As subsequently described in greater detail, source/drain regions will be subsequently formed in the source/drain recesses 94, and the dummy nanostructures 64A will be replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes, such as the etch processes used to form gate structures. Dielectric isolation layers 100, on the other hand, are used to isolate the upper semiconductor nanostructures 66U (collectively) from the lower semiconductor nanostructures 66L (collectively). Further, the middle semiconductor nanostructures 66M and the dielectric isolation layers 100 may define the boundaries of the lower nanostructure-FETs and the upper nanostructure-FETs.

The inner spacers 98 and the dielectric isolation layers 100 may be formed by conformally depositing an insulating material in the source/drain recesses 94, on sidewalls of the dummy nanostructures 64A, and between the middle semiconductor nanostructures 66M, and then etching the insulating material. The insulating material may be a non-low-k dielectric material, which may be a carbon-containing dielectric material such as silicon oxycarbonitride, silicon oxycarbide, or the like. The insulating material may be formed by a deposition process, such as ALD, CVD, or the like. The etching of the insulating material may be anisotropic or isotropic. The insulating material, when etched, has portions remaining in the sidewalls of the dummy nanostructures 64A (thus forming the inner spacers 98) and has portions remaining in between the middle semiconductor nanostructures 66M (thus forming the dielectric isolation layers 100).

As also illustrated by FIG. 6, lower epitaxial source/drain regions 108L and upper epitaxial source/drain regions 108U are formed. The lower epitaxial source/drain regions 108L are formed in the lower portions of the source/drain recesses 94. The lower epitaxial source/drain regions 108L are in contact with the lower semiconductor nanostructures 66L and are not in contact with the upper semiconductor nanostructures 66U. Inner spacers 98 electrically insulate the lower epitaxial source/drain regions 108L from the dummy nanostructures 64A, which will be replaced with replacement gates in subsequent processes.

The lower epitaxial source/drain regions 108L are epitaxially grown, and have a conductivity type that is suitable for the device type (p-type or n-type) of the lower nanostructure-FETs. When lower epitaxial source/drain regions 108L are n-type source/drain regions, the respective material may include silicon or carbon-doped silicon, which is doped with an n-type dopant such as phosphorous, arsenic, or the like. When lower epitaxial source/drain regions 108L are p-type source/drain regions, the respective material may include silicon or silicon germanium, which is doped with a p-type dopant such as boron, indium, or the like. The lower epitaxial source/drain regions 108L may be in-situ doped, and may be, or may not be, implanted with the corresponding p-type or n-type dopants. During the epitaxy of the lower epitaxial source/drain regions 108L, the upper semiconductor nanostructures 66U may be masked to prevent undesired epitaxial growth on the upper semiconductor nanostructures 66U. After the lower epitaxial source/drain regions 108L are grown, the masks on the upper semiconductor nanostructures 66U may then be removed.

As a result of the epitaxy processes used for forming the lower epitaxial source/drain regions 108L, upper surfaces of the lower epitaxial source/drain regions 108L have facets which expand laterally outward beyond sidewalls of the nanostructures 64 and 66. In some embodiments, adjacent lower epitaxial source/drain regions 108L remain separated after the epitaxy process is completed. In other embodiments, these facets cause neighboring lower epitaxial source/drain regions 108L of a same FET to merge.

A first contact etch stop layer (CESL) 112 and a first interlayer dielectric (ILD) 114 are formed over the lower epitaxial source/drain regions 108L. The first CESL 112 may be formed of a dielectric material having a high etching selectivity from the etching of the first ILD 114, such as silicon nitride, silicon oxide, silicon oxynitride, or the like, which may be formed by any suitable deposition process, such as CVD, ALD, or the like. The first ILD 114 may be formed of a dielectric material, which may be deposited by any suitable method, such as CVD, plasma-enhanced CVD (PECVD), or FCVD. The applicable dielectric material of the first ILD 114 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 114, followed by a planarization process and then an etch-back process. In some embodiments, the first ILD 114 is etched first, leaving the first CESL 112 unetched. An anisotropic etching process is then performed to remove the portions of the first CESL 112 higher than the recessed first ILD 114. After the recessing, the sidewalls of the upper semiconductor nanostructures 66U are exposed.

Upper epitaxial source/drain regions 108U are then formed in the upper portions of the source/drain recesses 94. The upper epitaxial source/drain regions 108U may be epitaxially grown from exposed surfaces of the upper semiconductor nanostructures 66U. The materials of upper epitaxial source/drain regions 108U may be selected from the same candidate group of materials for forming lower source/drain regions 108L, depending on the desired conductivity type of upper epitaxial source/drain regions 108U. The conductivity type of the upper epitaxial source/drain regions 108U may be opposite the conductivity type of the lower epitaxial source/drain regions 108L. For example, the upper epitaxial source/drain regions 108U may be oppositely doped from the lower epitaxial source/drain regions 108L. In some embodiments, the lower epitaxial source/drain regions 108L are of p-type, allowing for forming the lower nanostructure-FET as PFET, and the upper epitaxial source/drain regions 108U are of n-type, allowing for forming the upper nanostructure-FET as an NFET. Alternatively, in other embodiments, the lower epitaxial source/drain regions 108L are of n-type, allowing for forming the lower nanostructure-FET as an NFET, and the upper epitaxial source/drain regions 108U are of p-type, allowing for forming the upper nanostructure-FET as a PFET. The upper epitaxial source/drain regions 108U may be in-situ doped, and/or may be implanted, with an n-type or p-type dopant. Adjacent upper source/drain regions 108U may remain separated after the epitaxy process or may be merged.

After the epitaxial source/drain regions 108U are formed, a second CESL 122 and a second ILD 124 are formed. The materials and the formation methods may be similar to the materials and the formation methods of first CESL 112 and first ILD 114, respectively, and are not discussed in detail herein. The formation process may include depositing the layers for the second CESL 122 and the second ILD 124, and performing a planarization process to remove the excess portion of the corresponding layers. After the planarization process, top surfaces of the second ILD 124, the second CESL 122, the gate spacers 90, and the masks 86 are coplanar (within process variations). The planarization process may leave masks 86 unremoved (as shown), or may remove the masks 86, in which case the top surface of the second ILD 124 is level with the top surface of the dummy gate stacks 85.

Next, in FIGS. 7A and 7B, the mask 86 (if not removed already) is removed, e.g., by a CMP process. Next, the dummy gate stacks 85 are removed in one or more etching steps, so that gate trenches 126 are formed between the gate spacers 90. In some embodiments, the dummy gates 84 and the dummy dielectrics 82 are removed by an anisotropic dry etch process. For example, the etching process may include a dry etch process using reaction gas(es) that selectively etch the material of the dummy gates 84. Each of the gate trenches 126 exposes and/or overlies portions of nanostructures 64, 66 which act as the channel regions in the resulting devices. The portions of the nanostructures 64, 66 which act as the channel regions are disposed between neighboring pairs of the lower epitaxial source/drain regions 108L or between neighboring pairs of the upper epitaxial source/drain regions 108U. During the removal, the dummy dielectrics 82 may be used as etch stop layers when the dummy gates 84 are etched. The dummy dielectrics 82 may then be removed after the removal of the dummy gates 84.

The remaining portions of the first dummy nanostructures 64A are then removed to form openings 128 in regions between the semiconductor nanostructures 66. The remaining portions of the first dummy nanostructures 64A can be removed by any acceptable etch process that selectively etches the material of the first dummy nanostructures 64A at a faster rate than the materials of the semiconductor nanostructures 66, the inner spacers 98, and the isolation nanostructures 100. The etching may be isotropic. For example, when the first dummy nanostructures 64A are formed of silicon-germanium, the semiconductor nanostructures 66 are formed of silicon, the inner spacers 98 are formed of silicon oxycarbonitride, and the isolation nanostructures 100 are formed of silicon oxycarbonitride, the etch process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the semiconductor nanostructures 66 and expand the openings 128.

In FIGS. 8A-8B, gate dielectric layers 132 are formed (e.g., conformally) over the nanostructures 66. In some embodiments, as illustrated in FIG. 8A, interfacial layers 162 are formed at exposed surfaces of the nanostructures 66 and the fins 62. In some embodiments, the interfacial layer 162 is formed of an oxide of a group II-VI material or an oxide of a group IV material. In the illustrated embodiment, the interfacial layer 162 is an oxide of the material of the nanostructures 66, and is formed by an oxidization process (e.g., a thermal oxidization process). In other words, the interfacial layer 162 is formed by converting (e.g., oxidizing) exterior portions of the nanostructures 66 into an oxide of the material of the nanostructures 66, and by converting (e.g., oxidizing) exterior portions of the fins 62 into an oxide of the material of the fins 62. As a result, the interfacial layer 162 is not formed on, e.g., the isolation nanostructures 100 and the isolation regions 70, in the illustrated embodiment. In other embodiments, the interfacial layer 162 is formed by a deposition process (e.g., CVD), in which case the interfacial layer 162 is also formed on, e.g., the isolation nanostructures 100 and the isolation regions 70. In some embodiments, the interfacial layer 162 is omitted. These and other variations are fully intended to be included within the scope of the present disclosure.

The gate dielectric layers 132 are formed (e.g., conformally) over the interfacial layer 162 and along sidewalls of the isolation nanostructures 100, such that the gate dielectric layer 132 conformally lines the gate trenches 126 and the openings 128. Specifically, the gate dielectric layer 132 is formed on the top surfaces of the fins 62; on the top surfaces, the sidewalls, and the bottom surfaces of the semiconductor nanostructures 66; along sidewalls of the isolation nanostructures 100; and along the sidewalls of the gate spacers 90. The gate dielectric layer 132 wraps around all (e.g., four) sides of the semiconductor nanostructures 66. The gate dielectric layer 132 may also be formed on the sidewalls of the fins 62 (e.g., in embodiments where the top surfaces of the isolation regions 70 are below the top surfaces of the fins 62).

The gate dielectric layers 132 may include may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectric layer 132 may include molecular-beam deposition (MBD), ALD, PECVD, and the like.

In some embodiments, a first subset of the gate dielectric layers 132 surrounding the lower semiconductor nanostructures 66L has a different composition than a second subset of the gate dielectric layers 132 surrounding the upper semiconductor nanostructures 66U. This difference in composition allows both the lower nanostructure-FET and the upper nanostructure-FET to share a common gate metal composition, i.e., the same work function material and same fill metal material. For example, when the common gate metal composition includes a p-type work function layer, the gate dielectric layers 132 of an NFET can be doped with an n-type dipole dopant, such as La, Sr, Y, Er, Sc, Mg, or the like, or combinations thereof, while the gate dielectric layers 132 of a PFET can be free of the n-type dipole dopant. Similarly, when the common gate metal composition includes an n-type work function layer, the gate dielectric layers 132 of a PFET can be doped with a p-type dipole dopant, such as Al, Zn, Ga, or the like, or combinations thereof, while the gate dielectric layers 132 of an NFET can be free of the p-type dipole dopant.

In some embodiments, incorporating a dopant into the first subset of the gate dielectric layers 132 may include forming a patterned mask on the second subset of the gate dielectric layers 132, forming a dopant source layer on the first subset of the gate dielectric layers 132 but not on the second subset of the gate dielectric layers, followed by an anneal process performed to thermally diffuse the n-type dopant or p-type dopant from the dopant source layer into the first subset of the gate dielectric layers 132. Once the doping step is completed, the dopant source layer can be removed from the first subset of the gate dielectric layers 132, and the patterned mask can be removed from the second subset of the gate dielectric layers 132.

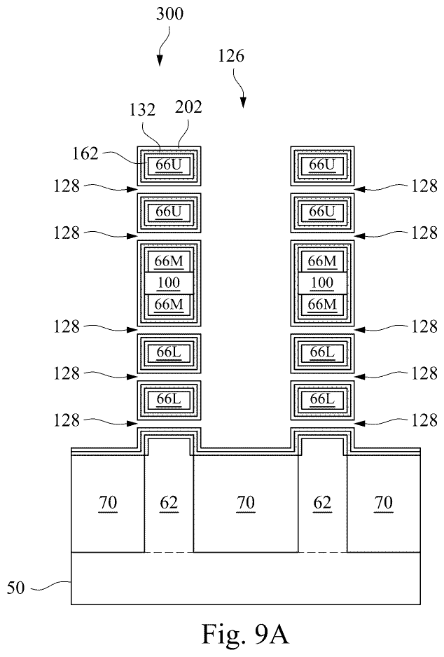

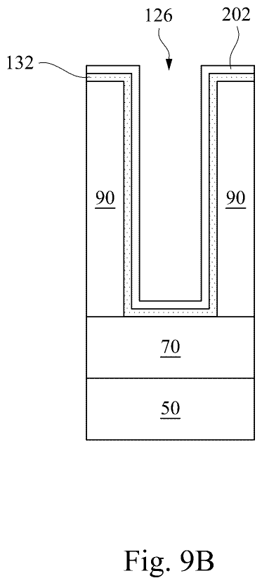

In FIGS. 9A-9B, a work function layer 202 is deposited in the gate trenches 126, surrounding the gate dielectric layers 132 as illustrated in FIG. 9A and lining the gate trenches 126 as illustrated in FIG. 9B. In some embodiments, portions of the work function layer 202 encircling each of the gate dielectric layers 132 may be physically separate from portions of the work function layer 202 encircling other ones of the gate dielectric layers 132. In this case, a subsequently formed fill metal (such as ruthenium, tungsten, cobalt, or the like) may fill the spaces between the portions of the work function layer 202 on neighboring ones of the gate dielectric layers 132. Alternatively, portions of the work function layer 202 encircling each of the gate dielectric layers 132 may be physically joined to portions of the work function layer 202 encircling other ones of the gate dielectric layers 132.

In some embodiments, the work function layer 202 has a p-type work function, which is higher than about 4.6 eV, and may be in the range between about 4.6 eV and about 5.2 eV. The p-type work function metal in the work function layer 202 for providing p-type work function may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some other embodiments, the work function layer 202 has an n-type work function lower than about 4.5 eV, and may be in the range between about 4.0 eV and about 4.5 eV. The n-type work function metal in the work function layer 202 for providing n-type work function may exemplarily include, but are not limited to, titanium aluminide (TiAl), titanium aluminium nitride (TiAlN), aluminum (Al), aluminum nitride (AlN), and/or other suitable materials.

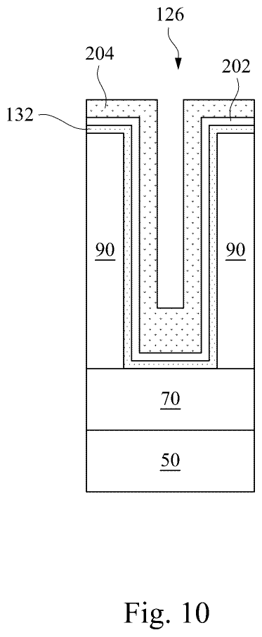

FIGS. 10-13 illustrate cross-sectional views at various stages of the deposition-etch-deposition (Dep-Etch-Dep) process for forming an improved gate fill metal structure, in accordance with some embodiments of the present disclosure. In FIG. 10, the Dep-Etch-Dep process begins with an initial deposition step that deposits a first fill metal 204 in the gate trenches 126. In some embodiments, the first fill metal 204 includes ruthenium, although alternative metals such as tungsten (W) may also be suitable. In some embodiments, the first fill metal 204 is deposited by using a suitable deposition technique, such as ALD. In some embodiments of depositing ruthenium using ALD, the process involves alternating exposure of the structure as illustrated in FIGS. 9A and 9B to ruthenium-containing precursors and a reactant gas, under low-pressure conditions to ensure high conformity and step coverage. In some embodiments, the ALD process for ruthenium may utilize ruthenium-containing precursors such as bis(ethylcyclopentadienyl)ruthenium or other organometallic compounds, which are introduced into the ALD reaction chamber in a cyclic manner. Each ALD cycle includes a ruthenium-containing precursor pulse, a purge step to remove excess ruthenium-containing precursor, a reactant pulse (such as oxygen or hydrogen), and a subsequent purge step to eliminate reaction by-products. This cyclic process allows for the deposition of ruthenium in a layer-by-layer fashion, ensuring that the first fill metal 204 conforms the underlying geometries of the gate trenches 126.

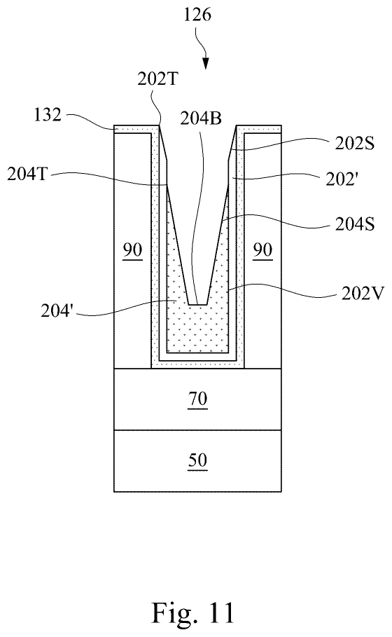

In the intermediate stage of the Dep-Etch-Dep process, as depicted in FIG. 11, the initial deposition step is followed by an etching step. In some embodiments, this etching step is performed using a wet etching process, specifically targeting both the first fill metal 204 (e.g., ruthenium) and the work function layer 202 (e.g., titanium nitride). This etching step serves to etch back the first fill metal 204 and the work function metal layer 202 to create a substantial “V-shaped” surface profile within the gate trench 126. This V-shaped profile can facilitate subsequent deposition steps, as it effectively widens the remaining space in the gate trench 126, thereby reducing the likelihood of void formation or reducing the void size during the final deposition step. The work function layer 202 and the first fill metal 204 experienced the etching step are denoted as the etched-back work function layer 202′ and the etched-back first fill metal 204', for the sake of clarity.

In some embodiments, the etchant employed in the etching step of the Dep-etch-Dep process includes a combination of an oxidizing agent and an acid, which together form a potent solution capable of etching both the first fill metal 204 (e.g., ruthenium) and the work function layer 202 (e.g., titanium nitride). In some embodiments, the oxidizing agent serves to oxidize the metal surfaces of the first fill metal 204 (e.g., ruthenium) and the work function layer 202 (e.g., titanium nitride), making them more susceptible to dissolution by the acid component of the etchant. This etching approach allows that both the first fill metal 204 (e.g., ruthenium) and the work function layer 202 (e.g., titanium nitride) are etched back simultaneously. Despite the concurrent etching of the first fill metal 204 and the work function layer 202, these materials exhibit different etch rates during this process. Specifically, the etching step is controlled to etch the first fill metal 204, such as ruthenium, at a faster rate compared to etching the work function layer 202, such as titanium nitride. This differential etch rate is advantageous as it allows the first fill metal 204 to be etched back more significantly than the work function layer 202. As a result, the etched-back first fill metal 204′ achieves a topmost position 204T that is lower than the topmost position 202T of the etched-back work function layer 202′.

In some embodiments, a top surface of the etched-back first fill metal 204′ has a bottom segment 204B and slanted segments 204S extending upwards from opposite ends of the bottom segment 204B at obtuse angles relative to the bottom segment 204B. Stated differently, a horizontal distance between the slanted segments 204S increases as a distance from the bottom segment 204B increases. In some embodiments, the slanted segments 204S terminate at respective vertical inner sidewalls 202V of the etched-back work function layer 202'. In some embodiments, the etched-back work function layer 202′ includes slanted sidewalls 202S extending upwards from the vertical inner sidewalls 202V. The slanted sidewalls 202S terminates at the topmost position 202T of the etched-back work function layer 202′. In some embodiments, the slanted sidewalls 202S of the etched-back work function layer 202′ have a different slope than the slanted segments 204S of the etched-back first fill metal 204′. For example, the slanted segments 204S of the etched-back first fill metal 204′ may have a steeper slope than the slanted sidewalls 202S of the etched-back work function 202′. In some embodiments, the slanted segments 204S of the etched-back first fill metal 204′ have a different length than the slanted sidewalls 202S of the etched-back work function layer 202′. For example, the slanted segments 204S of the etched-back first fill metal 204′ may have a greater length than the slanted sidewalls 202S of the etched-back work function layer 202′.

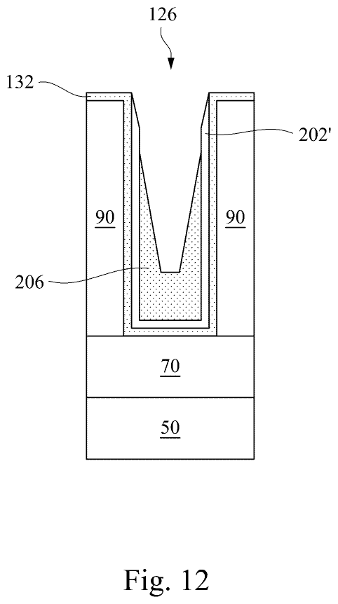

In the intermediate stage of the Dep-Etch-Dep process, as depicted in FIG. 12, the etching step is followed by an annealing step. In some embodiments, the annealing step may be performed using a mixture of inert gases and hydrogen gas. This annealing step serves to repair the metal surface (e.g. Ru surface) of the first fill metal 204′, reducing ruthenium oxide (RuO₂) from the surface of the first fill metal 204′, thereby facilitating the subsequently deposited second fill metal (e.g., Ru) to grow in a bottom-up manner within the gate trench 126. The bottom-up growth of Ru is facilitated by its preferential growth on existing Ru surfaces, which is a characteristic behavior of Ru during deposition processes.

In some embodiments, the annealing process contributes to the densification of the first fill metal 204', resulting in a densified first fill metal, denoted as 206 in FIG. 12. For example, the densified fill metal 206, such as densified Ru, may exhibit a density that is at least 5% greater than that of the initial first fill metal 204′, which consists of intrinsic Ru. Consequently, the density of the densified first fill metal 206 surpasses that of the second fill metal deposited in a subsequent step, even when the second fill metal shares the same metal composition, such as Ru, with the densified first fill metal 206. In some embodiments, this densification also affects the crystalline structure of the first fill metal, leading to a lattice configuration in the densified first fill metal 206 that differs from the second fill metal deposited later. In some embodiments, the enhanced density and altered lattice structure of the densified first fill metal 206 may provide a more favorable surface for the bottom-up growth of the second fill metal deposited later.

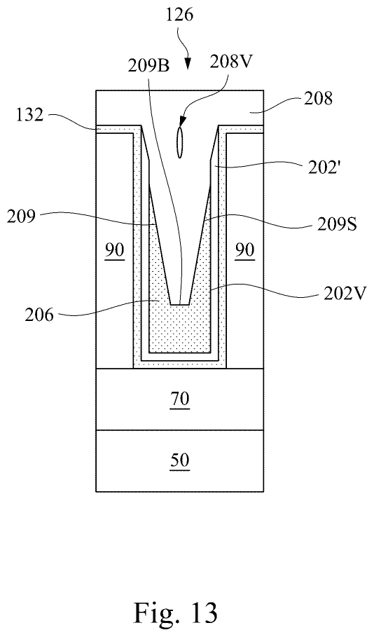

In the intermediate stage of the Dep-Etch-Dep process, as depicted in FIG. 13, the annealing step is followed by a final deposition step that deposits a second fill metal 208 overfilling the gate trenches 126. In some embodiments, the second fill metal 208 is formed of the same metal as the densified first fill metal 206 but has a density less than that of the densified first fill metal 206. For example, the densified first fill metal 206, such as densified Ru, may exhibit a density that is at least 5% greater than that of the second fill metal 208, which is formed of intrinsic Ru. Due to the difference in density, a distinguishable interface 209 may be formed between the densified first fill metal 206 and the un-densified second fill metal 208. The interface 209 follows the surface profile of the densified first fill metal 206 and thus includes a bottom segment 209B and slanted segments 209S extending upwards from opposite ends of the bottom segment 209B at obtuse angles relative to the bottom segment 209B. Stated differently, a horizontal distance between the slanted segments 209S increases as a distance from the bottom segment 209B increases. The slanted segments 209S terminate at respective vertical inner sidewalls 202V of the etched-back work function layer 202′.

In some embodiments, the second fill metal 208 includes ruthenium, although alternative metals such as tungsten (W) may also be suitable. In some embodiments, the second fill metal 208 is deposited by using a suitable deposition technique, such as ALD. In some embodiments of depositing ruthenium using ALD, the process involves alternating exposure of the structure as illustrated in FIG. 12 to ruthenium-containing precursors and a reactant gas, under low-pressure conditions to ensure high conformity and step coverage. In some embodiments, the ALD process for ruthenium may utilize ruthenium-containing precursors such as bis(ethylcyclopentadienyl)ruthenium or other organometallic compounds, which are introduced into the ALD reaction chamber in a cyclic manner. Each ALD cycle includes a ruthenium-containing precursor pulse, a purge step to remove excess ruthenium-containing precursor, a reactant pulse (such as oxygen or hydrogen), and a subsequent purge step to eliminate reaction by-products.

In some embodiments where the second fill metal 208 and the densified first fill metal 206 are both formed Ru and the work function layer 202′ includes a non-Ru metal, the second fill metal 208 can be deposited on the densified first fill metal 206 at a faster deposition rate than on the non-Ru work function layer 202′. This difference in deposition rate allows for growing the second fill metal 208 in a substantial bottom-up manner, which allows for forming no or negligible void in the second gate fill metal 208.

The bottom-up growth mechanism can be attributed to the surface energy dynamics between the Ru of the second fill metal 208 and the underlying densified first fill metal 206. The densified Ru surface of the densified first fill metal 206, having undergone annealing, presents a surface with increased density and potentially altered lattice structure, which enhances the nucleation and growth of the second fill metal 208. This preferential nucleation can be further influenced by deposition conditions such as temperature, pressure, and the chemical nature of the precursors used in the ALD process. By controlling these parameters, selective growth on the densified Ru surface of the first fill metal 206 can be promoted, while deposition on the non-Ru work function layer 202′ can be inhibited. In some embodiments, even if the deposition behavior of the second fill metal 208 does not achieve an ideal bottom-up growth, the size and/or location of any potential void 208V can still be confined by the “V-shaped” profile on the top surface of the densified first fill metal 206. For instance, the void 208V may be significantly smaller than those found in fill metal structures formed using existing methods, which do not employ the Dep-Etch-Dep technique. Consequently, the impact of any voids in the fill metal is mitigated by the Dep-Etch-Dep technique, enhancing the overall structural integrity and performance of the semiconductor device.

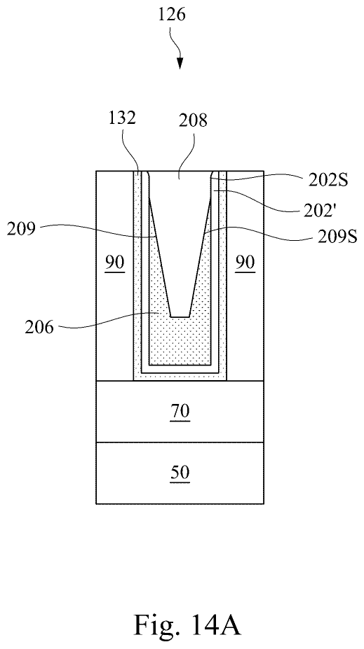

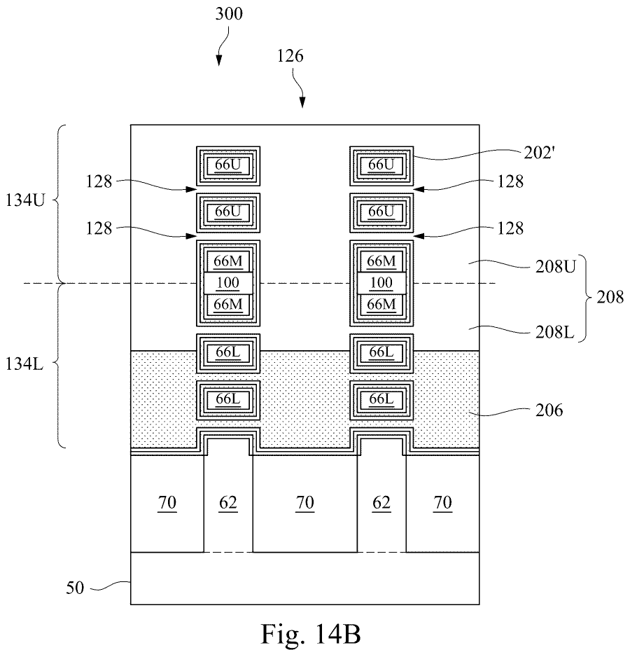

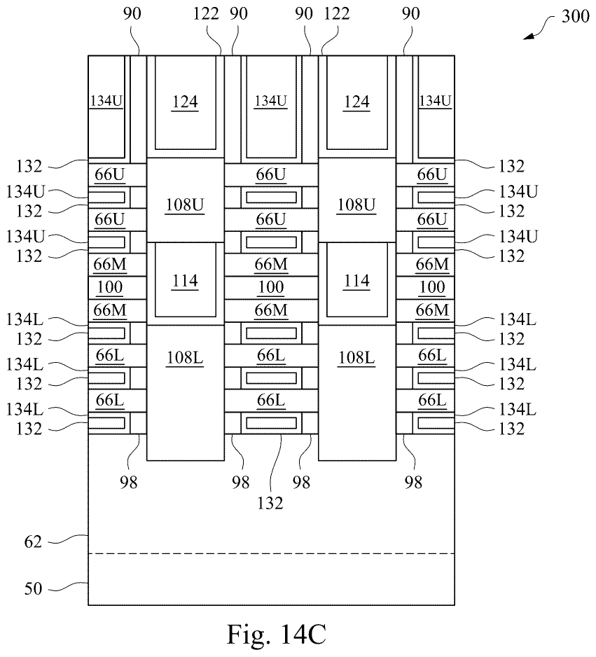

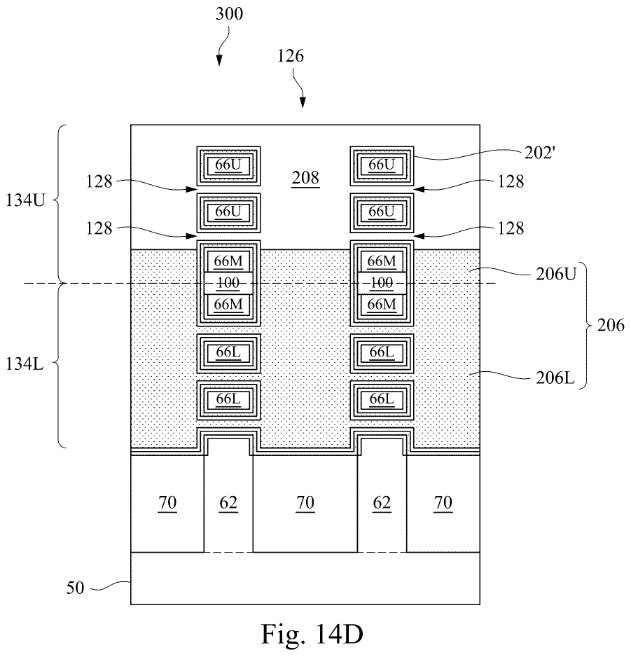

Next, a CMP process is performed on the second fill metal 208 to remove excess materials of the second fill metal 208 and the gate dielectric layer 132 outside the gate trench 126, until the gate spacers 90 get exposed. The resultant structure is illustrated in FIGS. 14A-14C. As illustrated in FIG. 14B, metal materials in a lower portion of the gate trench 126 below the isolation nanostructures 100 are collectively referred to as a lower gate electrode 134L. On the other hand, metal materials in an upper portion of the gate trench 126 above the isolation nanostructures 100 are collectively referred to as an upper gate electrode 134U. In some embodiments, while the upper gate electrode 134U and the lower gate electrode 134L share the same composition and number of work function layers 202′, they differ in their fill metal structures.

For example, as illustrated in FIG. 14B, the lower gate electrode 134L includes the work function layer 202′ surrounding lower semiconductor nanostructures 66L, the densified first fill metal 206, and a lower portion 208L of the second fill metal 208. The densified first fill metal 206 and the lower portion 208L of the second fill metal 208 collectively serve as a fill metal structure of the lower gate electrode 134L, filling up the lower portion of the gate trench 126. On the other hand, the upper gate electrode 134U includes the work function layer 202′ surrounding upper semiconductor nanostructures 66U, and an upper portion 208U of the second fill metal 208, but is free of the densified first fill metal 206. The absence of the densified first fill metal 206 in the upper gate electrode 134U may result from the initial deposition step depicted in FIG. 10, which might have been halted before the upper portion of the gate trench 126 was filled. Alternatively, it could be due to the etch step shown in FIG. 11, which may have removed the first fill metal from the upper portion of the gate trench 126. In these scenarios, the upper portion 208U of the second fill metal 208 alone serves as the fill metal structure of the upper gate electrode 134U, filling the upper portion of the gate trench 126.

In alternative embodiments, as illustrated in FIG. 14D, the lower gate electrode 134L includes the work function layer 202′ surrounding lower semiconductor nanostructures 66L and a lower portion 206L of the densified first fill metal 206, without the presence of the second fill metal 208. On the other hand, the upper gate electrode 134U comprises the work function layer 202′ surrounding upper semiconductor nanostructures 66U, an upper portion 206U of the densified first fill metal 206, and the second fill metal 208. These scenarios may arise from the initial deposition step illustrated in FIG. 10, which might have filled a lower part of the upper portion of the gate trench 126.

As illustrated in FIG. 14A, upon completion of the CMP process, lower portions of the slanted sidewalls 202S of the work function layer 202′ may still remain in the gate trench 126. The remaining slanted sidewalls 202S may be evidence that the work function layer 202′ has experienced an etching step as illustrated in FIG. 11. Moreover, the slanted segments 209S of the interface 209 between the densified first fill metal 206 and the un-densified second fill metal 208 may be evidence that the first fill metal has experienced an etching step as illustrated in FIG. 11. Moreover, the difference in density between the densified first fill metal 206 and the un-densified second fill metal 208 may be evidence that the first fill metal has experienced an annealing process as illustrated in FIG. 12, and the second fill metal 208 is formed after the annealing process. In some embodiments, the interfacial layers 162, and detailed layers of the lower and upper electrodes 134L, 134U are not illustrated in FIG. 14C for the sake of clarity.

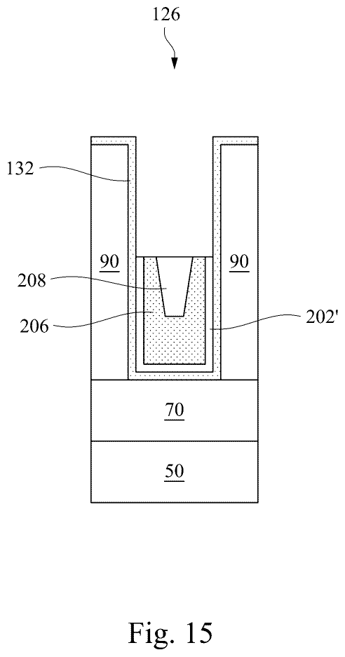

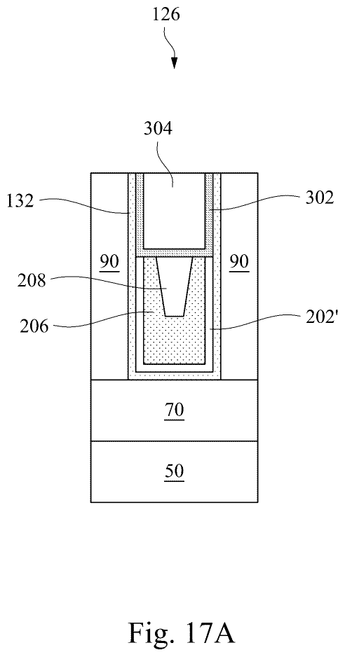

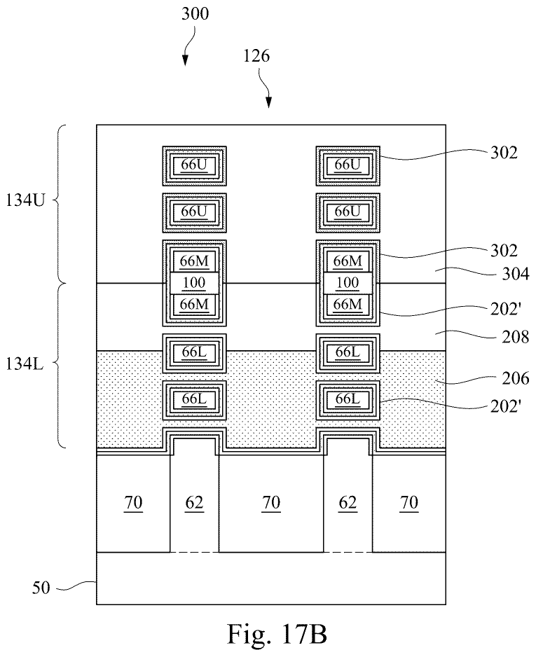

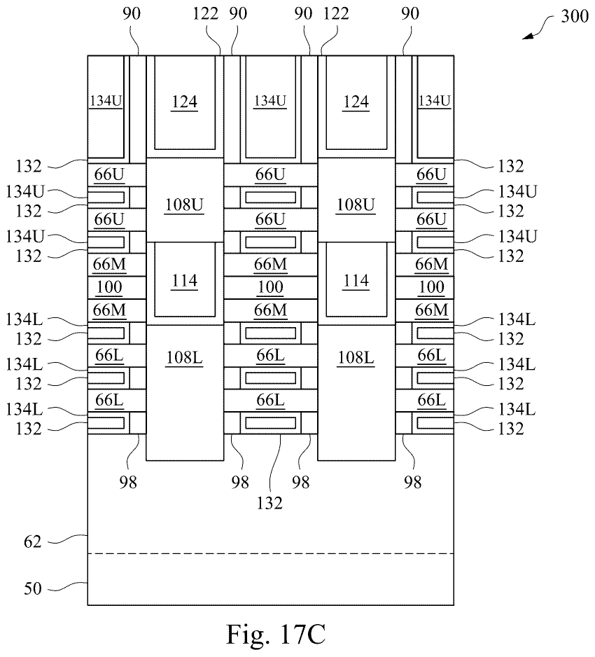

FIGS. 15-17C are cross-sectional views of a CFET device at various stages of manufacturing, in accordance with some other embodiments of the present disclosure. FIGS. 15-17A illustrate cross-sectional views along a similar cross-section as reference cross-section C-C′ in FIG. 1. FIG. 17B illustrates a cross-sectional view along a similar cross-section as reference cross-section B-B′ in FIG. 1. FIG. 17C illustrates a cross-sectional view along a similar cross-section as reference cross-section A-A′ in FIG. 1. The intermediate stage illustrated in FIG. 15 may be subsequent to the intermediate stage as illustrated in FIG. 13, wherein a metal gate etch back (MGEB) process is performed to selectively etch back the metal materials including the second fill metal 208, the densified first fill metal 206, and the work function layer 202′, until the upper portion of the gate trench 126 is free of these metal material.

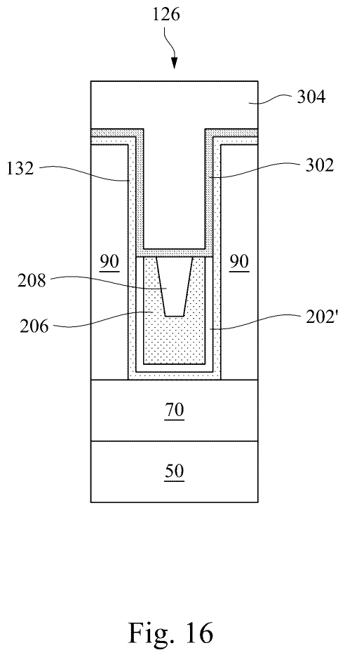

Next, in FIG. 16, another work function layer 302 is deposited within the upper portion of the gate trench 126, followed by depositing a third fill metal 304 to overfilling the upper portion of the gate trench 126. In some embodiments, the work function layer 302 is formed of a different work function metal than the work function layer 202. For example, if the work function layer 202′ is formed of a work function metal (e.g., TiN) having a p-type work function, then the work function layer 302 is formed of a work function metal (e.g., TiAl) having an n-type work function. In some embodiments the third fill metal 304 is formed of a different metal than the densified first fill metal 206 and the second fill metal 208. For example, if the first and second fill metals 206 and 208 are formed of Ru, then the third fill metal 304 is formed of a non-Ru metal, such as TiN.

Next, a CMP process is performed on the third fill metal 304 to remove excess materials of the third fill metal 304, the work function layer 302, and the gate dielectric layer 132 outside the gate trench 126, until the gate spacers 90 get exposed. The resultant structure is illustrated in FIGS. 17A-17C. As illustrated in FIG. 17B, metal materials in a lower portion of the gate trench 126 below the isolation nanostructures 100 are collectively referred to as a lower gate electrode 134L. On the other hand, metal materials in an upper portion of the gate trench 126 above the isolation nanostructures 100 are collectively referred to as an upper gate electrode 134U. In some embodiments, while the upper gate electrode 134U and the lower gate electrode 134L are different in both the work function material and the fill metal material.

For example, as illustrated in FIG. 17B, the lower gate electrode 134L includes the work function layer 202′ surrounding lower semiconductor nanostructures 66L, the densified first fill metal 206, and the second fill metal 208. The densified first fill metal 206 and the second fill metal 208 collectively serve as a fill metal structure of the lower gate electrode 134L, filling up the lower portion of the gate trench 126. On the other hand, the upper gate electrode 134U includes the work function layer 302 surrounding upper semiconductor nanostructures 66U, and the third fill metal 304. The third fill metal 304 alone serves as the fill metal structure of the upper gate electrode 134U, filling the upper portion of the gate trench 126. In some embodiments, the interfacial layers 162, and detailed layers of the lower and upper electrodes 134L, 134U are not illustrated in FIG. 17C for the sake of clarity.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the deposition-etch-deposition (Dep-Etch-Dep) process allows for forming an improved gate fill metal structure with no or negligible voids. Another advantage is that the performance and reliability of CFETs can be improved by reducing void formation in the gate fill metal structure.

In some embodiments, a method includes forming a first semiconductor channel region and a second semiconductor channel region above the first semiconductor channel region; forming a first work function layer surrounding the first semiconductor channel region and the second semiconductor channel region; depositing a first fill metal over the first work function layer; etching back the first fill metal; and depositing a second fill metal over the etched-back first fill metal. The etched-back first fill metal has a non-linear top surface in a cross-sectional view. The non-linear top surface comprises a bottom segment and slanted segments extending upwards from opposite ends of the bottom segment. In some embodiments, the method further includes etching back the first work function layer. The etched-back first work function layer comprises slanted inner sidewalls in the cross-sectional view. In some embodiments, the slanted inner sidewalls of the etched-back first work function layer have a different slope than the slanted segments of the non-linear top surface of the etched-back first fill metal. In some embodiments, the first fill metal and the first work function layer are etched back in a same etching step. In some embodiments, the method further includes performing an annealing process on the first fill metal. In some embodiments, the annealing process is performed after etching back the first fill metal. In some embodiments, a density of the first fill metal is increased by the annealing process. In some embodiments, the second fill metal and the first fill metal comprise a same metal element. In some embodiments, the second fill metal and the second fill metal are both ruthenium. In some embodiments, the method further includes etching back the second fill metal; removing the first work function layer from the second semiconductor channel region; depositing a second work function layer around the second semiconductor channel region; and depositing a third fill metal over the etched-back second fill metal.

In some embodiments, a method includes forming a first semiconductor nanostructure above a substrate, and a second semiconductor nanostructure above the first semiconductor nanostructure; forming a dielectric isolation nanostructure between the first semiconductor nanostructure and the second semiconductor nanostructure; forming a gate dielectric layer surrounding the first semiconductor nanostructure, the dielectric isolation nanostructure, and the second semiconductor nanostructure; depositing a first fill metal over the gate dielectric layer; performing an annealing process on the first fill metal; and after performing the annealing process on the first fill metal, depositing a second fill metal over the first fill metal. In some embodiments, the second fill metal and the first fill metal are made of a same material. In some embodiments, the second fill metal has a different density than the first fill metal. In some embodiments, the second fill metal has a less density than the first fill metal. In some embodiments, the method further includes etching the first fill metal prior to performing the annealing process. In some embodiments, after etching the first fill metal, a top surface of the first fill metal has a slanted segments separated by a horizontal distance. The horizontal distance decreases in a direction towards the substrate.

In some embodiments, a device includes a first semiconductor channel region between gate spacers; a second semiconductor channel region between the gate spacers and above the first semiconductor channel region; and a gate electrode between the gate spacer and surrounding both the first semiconductor channel region and the second semiconductor channel region. The gate electrode includes a first fill metal in a lower portion of a gate trench, and a second fill metal in an upper portion of the gate trench. The second fill metal forms an interface with the first fill metal. In a cross-sectional view, the interface formed by the first fill metal and the second fill metal has a bottom segment and slanted segments extending upwards from opposite ends of the bottom segment. The horizontal distance between the slanted segments increases as a distance from the bottom segment increases. In some embodiments, the first fill metal and the second fill metal are both ruthenium. In some embodiments, the first fill metal has a density greater than a density of the second fill metal. In some embodiments, in the cross-sectional view, the gate electrode comprises a work function layer having slanted sidewalls above the slanted segments of the interface formed by the first fill metal and the second fill metal.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first semiconductor channel region and a second semiconductor channel region above the first semiconductor channel region;
forming a first work function layer surrounding the first semiconductor channel region and the second semiconductor channel region;
depositing a first fill metal over the first work function layer;
etching back the first fill metal, wherein the etched-back first fill metal has a non-linear top surface in a cross-sectional view, and the non-linear top surface comprises a bottom segment and slanted segments extending upwards from opposite ends of the bottom segment; and
depositing a second fill metal over the etched-back first fill metal.

2. The method of claim 1, further comprising:
etching back the first work function layer, wherein the etched-back first work function layer comprises slanted inner sidewalls in the cross-sectional view.

3. The method of claim 2, wherein the slanted inner sidewalls of the etched-back first work function layer have a different slope than the slanted segments of the non-linear top surface of the etched-back first fill metal.

4. The method of claim 2, wherein the first fill metal and the first work function layer are etched back in a same etching step.

5. The method of claim 1, further comprising:
performing an annealing process on the first fill metal.

6. The method of claim 5, wherein the annealing process is performed after etching back the first fill metal.

7. The method of claim 5, wherein a density of the first fill metal is increased by the annealing process.

8. The method of claim 1, wherein the second fill metal and the first fill metal comprise a same metal element.

9. The method of claim 1, wherein the second fill metal and the second fill metal are both ruthenium.

10. The method of claim 1, further comprising:
etching back the second fill metal;
removing the first work function layer from the second semiconductor channel region;
depositing a second work function layer around the second semiconductor channel region; and
depositing a third fill metal over the etched-back second fill metal.

11. A method, comprising:
forming a first semiconductor nanostructure above a substrate, and a second semiconductor nanostructure above the first semiconductor nanostructure;
forming a dielectric isolation nanostructure between the first semiconductor nanostructure and the second semiconductor nanostructure;
forming a gate dielectric layer surrounding the first semiconductor nanostructure, the dielectric isolation nanostructure, and the second semiconductor nanostructure;
depositing a first fill metal over the gate dielectric layer;
performing an annealing process on the first fill metal; and
after performing the annealing process on the first fill metal, depositing a second fill metal over the first fill metal.

12. The method of claim 11, wherein the second fill metal and the first fill metal are made of a same material.

13. The method of claim 12, wherein the second fill metal has a different density than the first fill metal.

14. The method of claim 12, wherein the second fill metal has a less density than the first fill metal.

15. The method of claim 11, further comprising:
etching the first fill metal prior to performing the annealing process.

16. The method of claim 15, wherein after etching the first fill metal, a top surface of the first fill metal has a slanted segments separated by a horizontal distance, wherein the horizontal distance decreases in a direction towards the substrate.

17. A device, comprising:
a first semiconductor channel region between gate spacers;
a second semiconductor channel region between the gate spacers and above the first semiconductor channel region; and
a gate electrode between the gate spacer and surrounding both the first semiconductor channel region and the second semiconductor channel region, the gate electrode comprising a first fill metal in a lower portion of a gate trench, and a second fill metal in an upper portion of the gate trench, the second fill metal forming an interface with the first fill metal, wherein in a cross-sectional view, the interface formed by the first fill metal and the second fill metal has a bottom segment and slanted segments extending upwards from opposite ends of the bottom segment, wherein a horizontal distance between the slanted segments increases as a distance from the bottom segment increases.

18. The device of claim 17, wherein the first fill metal and the second fill metal are both ruthenium.

19. The device of claim 18, wherein the first fill metal has a density greater than a density of the second fill metal.

20. The device of claim 17, wherein in the cross-sectional view, the gate electrode comprises a work function layer having slanted sidewalls above the slanted segments of the interface formed by the first fill metal and the second fill metal.
